(19) United States
(12) Patent Application Publication
(10) Pub. No.: US 2025/0194098 A1
(43) Pub. Date: Jun. 12, 2025

(54) STRUCTURE WITH FERROELECTRIC MEMORY STACKS HAVING DIFFERENT SWITCHING VOLTAGES AND RELATED METHODS

(71) Applicant: GlobalFoundries Dresden Module One Limited Liability Company & Co. KG, Dressden (DE)

(72) Inventors: Stefan Dünkel, Dresden (DE); Dominik Martin Kleimaier, Dresden (DE); Halid Mulaosmanovic, Dresden (DE); Johannes Müller, Dresden (DE)

(21) Appl. No.: 18/534,863

(22) Filed: Dec. 11, 2023

(51) Int. Cl. H10B 53/30; H01L 23/528; H01L 29/66; H01L 29/78; H10B 51/30

(52) U.S. Cl. CPC H10B 53/30; H01L 23/5283; H10B 51/30; H10D 30/0415; H10D 30/701

(57) ABSTRACT

The disclosure provides a structure with ferroelectric memory stacks having different switching voltages, and methods to provide the same. A structure of the disclosure includes a first ferroelectric memory stack over a substrate. The first ferroelectric memory stack has a first switching voltage. A second ferroelectric memory stack is serially coupled to the first ferroelectric memory stack over the substrate. The second ferroelectric memory stack has a second switching voltage, different from the first switching voltage.

### BACKGROUND

The present disclosure relates generally to integrated circuits, and more specifically, to structures and methods to provide ferroelectric memory stacks.

Memory cells are important to the operation of integrated circuits (ICs). Memory cells may include a collection of electrically operated components, e.g., transistors, that can be read and/or written in any order and can electrically store working data or machine code for a device. Non-volatile memory, in particular, is capable of holding data even when there is no power to the device. Various forms of non-volatile memory operate by physically or electrically modifying certain active materials, such that any information recorded in such modifications will remain within a device when its power supply turns off. In an array of non-volatile memory cells, each data may be programmed into each cell as a “one” or “zero” by selecting desired cells via a set of corresponding transistors and applying a programming voltage to the selected cells. In conventional memory arrays, each memory cell can only hold one bit of data.

### SUMMARY

An aspect of the disclosure is directed to structure including: a first ferroelectric memory stack over a substrate, the first ferroelectric memory stack having a first switching voltage; and a second ferroelectric memory stack serially coupled to the first ferroelectric memory stack over the substrate, the second ferroelectric memory stack having a second switching voltage different from the first switching voltage.

Another aspect of the disclosure provides a structure including: a first ferroelectric memory stack including: an insulative layer on an upper surface of a substrate, a first ferroelectric layer on the insulative layer, and a first conductive plate on the first ferroelectric layer, wherein the first ferroelectric memory stack has a first switching voltage; and a second ferroelectric memory stack within a metal wiring layer and serially coupled to the first ferroelectric memory stack, the second ferroelectric memory stack including: a second conductive plate within the metal wiring layer, a second ferroelectric layer on the second conductive plate, and a third conductive plate on the second ferroelectric layer, wherein the second ferroelectric memory stack has a second switching voltage different from the first switching voltage such that a first bit stored within the second ferroelectric memory stack is independently adjustable relative to a second bit stored within the second ferroelectric memory stack.

An aspect of the disclosure provides a method including: forming a first ferroelectric memory stack over a substrate, the first ferroelectric memory stack having a first switching voltage; forming a second ferroelectric memory stack serially coupled to the first ferroelectric memory stack over the substrate, the second ferroelectric memory stack having a second switching voltage; and applying a voltage across the first ferroelectric memory stack and the second ferroelectric memory stack to adjust one of a first bit stored within the first ferroelectric memory stack and a second bit stored within the second ferroelectric memory stack.

The foregoing and other features of the disclosure will be apparent from the following more particular description of embodiments of the disclosure.

### BRIEF DESCRIPTION OF THE DRAWINGS

The embodiments of this disclosure will be described in detail, with reference to the following figures, wherein like designations denote like elements, and wherein:

FIGS. 1A and 1B show a perspective views of a conventional ferromagnetic transistor in different states.

FIG. 2 shows a cross-sectional view of a structure according to embodiments of the disclosure.

FIG. 3 shows a cross-sectional view of a structure with different ferromagnetic layer compositions according to embodiments of the disclosure.

FIG. 4 shows a cross-sectional view of a structure with different ferromagnetic layer thicknesses according to embodiments of the disclosure.

FIG. 5 shows a cross-sectional view of a structure with different ferromagnetic layer cross-sectional areas according to embodiments of the disclosure.

FIG. 6 shows a cross-sectional view of a structure with ferromagnetic layers above a device layer according to embodiments of the disclosure.

FIG. 7 provides a table relating polarizations to bits stored and example voltage pulses for operating a structure according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

The disclosure provides a structure with ferroelectric memory stacks having different switching voltages, and methods to provide the same. A structure of the disclosure includes a first ferroelectric memory stack over a substrate. The first ferroelectric memory stack has a first switching voltage. A second ferroelectric memory stack is serially coupled to the first ferroelectric memory stack over the substrate. The second ferroelectric memory stack has a second switching voltage, different from the first switching voltage.

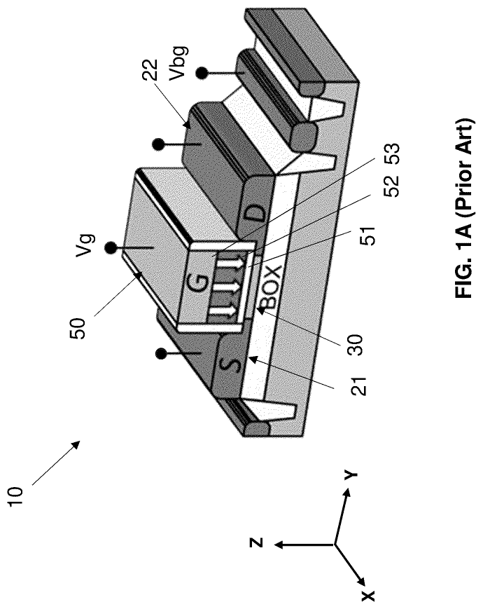

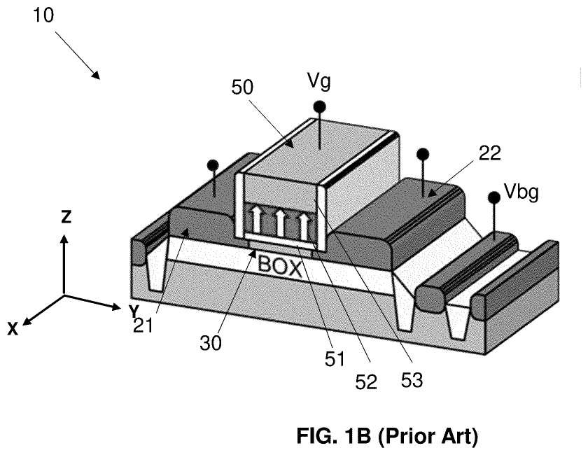

FIGS. 1A and 1B depict a memory transistor 10 and, particularly, a ferroelectric field effect transistor (FeFET) for providing non-volatile memory by storing electrical data within a gate structure. Memory transistor 10 could be a semiconductor-on-insulator structure, as illustrated. Alternatively, memory transistor 10 could be a bulk semiconductor structure. In any case, memory transistor 10 includes a source region 21, a drain region 22, and a channel region 30 positioned laterally between source and drain regions 21-22. Memory transistor 10 can be an N-type FeFET. In this case, source and drain regions 21-22 can be doped so as to have N-type conductivity at a relatively high conductivity level. Channel region 30 can be an intrinsic channel region (i.e., an undoped channel region) or can be doped so as to have P-type conductivity at a relatively low conductivity level (i.e., a P-channel region). Memory transistor 10 can further include a gate 50 adjacent to channel region 30. Gate 50 can be a multi-layered gate structure including, for example, a gate dielectric layer 51 adjacent the channel region 30, a ferroelectric dielectric material layer 52 (e.g., a hafnium oxide layer or some other suitable ferroelectric dielectric material layer) on the dielectric layer 51, and a gate conductor layer 53 (e.g., a gate metal layer). During a write operation, specific voltage conditions can be established on the gate and source and drain regions (e.g., using gate voltage Vg) so that the memory transistor 10 is either programmed so that it has a low threshold voltage (VT) (thereby storing a “1”) (see FIG. 1A) or erased so that it has a high VT (thereby storing a “0”) (see FIG. 1B). For example, to program an N-type FeFET (i.e., achieve a low VT and store a “1”), a positive voltage can be applied to gate 30 and source and drain regions 21-22 can be connected to ground. As a result, the direction of polarization vector in the ferroelectric dielectric material layer 52 points towards the channel region 30, thereby attracting electrons into the channel region 30 and reducing VT (see FIG. 1A). To erase the N-type FeFET (i.e., achieve a high VT and store a “0” in the memory transistor 10), a negative voltage can be applied to gate 30 and source and drain regions 21-22 can again be connected to ground. As a result, the direction of polarization vector in the ferroelectric dielectric material layer 52 points away from channel region 30, thereby repelling electrons from the channel region 30 and increasing VT (see FIG. 1A). In other words, the ferroelectric dielectric material layer 52 within gate 50 is capable of having a positive (i.e., upward) oriented electric field or negative (i.e., downward) oriented electric field. Applying a gate voltage (Vg) to gate G of at least a threshold magnitude may cause ferroelectric material within the gate to switch between the positive or negative orientation. Conventional memory transistor 10, as shown and described, can only retain one logic level (and hence one binary digit or “bit”) at a time.

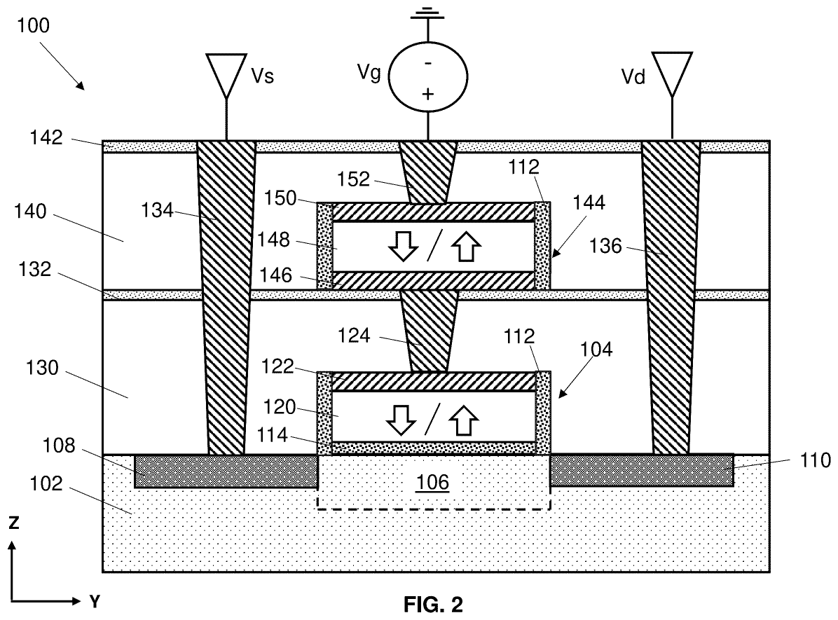

Turning to FIG. 2, embodiments of the disclosure provide a structure 100 for storing multiple bits of data as non-volatile memory through multiple ferroelectric memory stacks, and by structural and operational features not provided in conventional memory transistor 10 (FIG. 1). Structure 100 may be formed on a substrate 102, e.g., one or more semiconductor materials. Substrate 102 may include but is not limited to silicon, germanium, silicon germanium, silicon carbide, or any other common IC semiconductor substrates. A portion or entire semiconductor substrate 102 may be strained. Substrate 102 is illustrated as a bulk semiconductor layer, but this is not required in all implementations. Structure 100 may include a first ferroelectric memory stack (“first stack” hereafter) 104 located over a portion of substrate 102. First stack 104 may be provided in the form of a gate stack for the FeFET (e.g., an N-type FeFET) and may include various layers, components, etc., for influencing the conductivity in a channel region 106 of substrate 102 as discussed herein. Various portions of substrate 102 may be doped with p-type and/or n-type dopants to provide a desired conductivity type.

Portions of substrate 102 may be doped to form electrically active source/drain (“S/D”) regions of the FeFET, e.g., a set of source regions 108 and a set of drain regions 110 (collectively “S/D regions” 108, 110 hereafter). S/D regions 108, 110 are doped, electrically active regions in substrate 102 that define opposite terminals for current flow below first stack 104. When first stack 104 is electrically biased, components thereof (e.g., a first ferroelectric layer 120 as discussed herein) may create an electric field through channel region 106 to influence its conductivity, thus enabling or preventing current flow between source region 108 and drain region 110. As will be recognized, S/D regions 108, 110 are doped with a dopant having a selected polarity for a respective transistor. An n-type transistor may include n-type dopants such as but not limited to: phosphorous (P), arsenic (As), antimony (Sb), and a p-type transistor may include p-type dopants such as but not limited to: boron (B), indium (In) and gallium (Ga).

First stack 104 may include spacers 112 on its sidewalls, e.g., one or more bodies of insulating material formed on the upper surface of a material, e.g., by deposition, thermal growth, etc., to electrically and physically insulate materials subsequently formed on the coated material(s) from other components. According to an example, spacer(s) 112 may have one or more oxide insulator materials (e.g., SiO₂) formed to a desired thickness. In this case, spacer(s) 112 alternatively may be formed, e.g., by oxidizing exposed outer surfaces of semiconductor material(s) within first stack 104 to convert its material composition into an oxide insulator (e.g., converting from poly-Si to silicon dioxide (SiO₂) or other semiconductor oxides).

First stack 104 may include a gate dielectric layer 114 on channel region 106. Gate dielectric layer 114 may include any thin layer of dielectric material capable of preventing electrical coupling between channel region 106 and electrically active material(s) over gate dielectric layer 114 while allowing electric fields within first stack 104 (e.g., those from within first ferroelectric layer 120) to influence the electrical conductivity within channel region 106. Gate dielectric layer 114 may include, e.g., a “high-k” dielectric material (i.e., any material having a dielectric constant of at least 3.9) or other currently known or later developed gate dielectric materials, and as examples may include hafnium silicate (HfSiO), hafnium oxide (HfO₂), zirconium silicate (ZrSiOₓ), zirconium oxide (ZrO₂), silicon oxide (SiO₂), silicon nitride (Si₃N₄), silicon oxynitride (SiON), or any combination of these materials.

First stack 104 includes first ferroelectric layer 120 on gate dielectric layer 114. A “ferroelectric layer” refers to any material exhibiting spontaneous electric polarization oriented in a particular direction. Such materials may include oxide-based dielectric materials and/or other types of dielectric layers suitable for use in a capacitive structure (i.e., between two conductive plates) and/or within a transistor structure beneath a gate metal. As discussed herein, such materials may include hafnium oxide (HfO₂), hafnium-zirconium oxide (HZO), and/or other materials having similar properties. An external electric field of at least a minimum voltage magnitude (i.e., a “switching voltage”) may be effective to reverse the orientation of the electric polarization in first ferroelectric layer 120. For instance, first ferroelectric layer 120 may include one or more materials having a switching voltage of four volts (V) may switch from a negative orientation to a positive orientation when electrically biased at +4.0 V or more and may switch from a positive orientation to a negative orientation when electrically biased at-4.0 V or less. Any layer having an upward and downward arrow in the accompanying FIGS. indicates that this layer may be polarized in either direction, thus functioning as a type of first ferroelectric layer 120. Positive or negative biasing voltages having a magnitude that is less than the switching voltage may not affect the electric polarization in first ferroelectric layer 120. First stack 104 also may include a first conductive plate (“first plate”) 122 on first ferroelectric layer 120, e.g., to form a physical and electric point of contact between first stack 104 and any conductive materials thereon. First plate 122 may include any currently known or later developed material appropriate for use as and/or within microelectronic wiring, e.g., tungsten (W), copper (Cu), aluminum (Al), etc. During operation, first stack 104 may function as a transistor gate (i.e., by controlling the conductivity through channel region 106 of a FeFET), e.g., by selectively storing a logic level in first ferroelectric layer 120 via the switchable field orientation therein. In further embodiments discussed herein, the same structure or similar structure may function as a capacitor.

Structure 100 may include an inter-level dielectric (ILD) layer 130 on substrate 102 and above channel region(s) 106, source region(s) 108, drain region(s) 110, and first stack 104. ILD layer 130 may include any currently known or later developed insulating material appropriate for separating various layers of a device from each other, e.g., any material also appropriate for use as or within a trench isolation (TI) for electrically separating various regions of active semiconductor material. Such materials may include, without limitation: silicon nitride (Si₃N₄), silicon oxide (SiO₂), fluorinated SiO₂ (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, a spin-on silicon-carbon containing polymer material, near frictionless carbon (NFC), or layers thereof. However embodied, ILD layer 130 may vertically separate active materials from overlying materials, e.g., various horizontally extending wires or vias. ILD layer 130 may be formed by deposition and/or other techniques to provide electrically insulating materials, and can then be planarized (e.g., using CMP). Multiple ILD layers 130 may be present in structure 100, in which case a set of insulative liners 132 may vertically separate each ILD layer 130 from each other. Insulative liners 132 may include a different type of insulator from ILD layer(s) 130, e.g., it may include nitride in the case where ILD layer(s) 130 include oxide insulators. Insulative liners 132, during processing, may function as “etch stop layers” to control where certain wires, vias, etc., will be formed in structure 100.

A first contact 124 may be within ILD layer 130 and on first plate 122, e.g., to define the electrical pathway for biasing voltages applied to first stack 104. As discussed herein, first contact 124 itself may be coupled to a second stack 144 and thus connects first stack 104 to second stack 144 in series. First contact 124 may have an upper surface that interfaces with a lowermost surface of second stack 144 and a lower surface that interfaces with first plate 122 of first stack 104. Structure 100 also may include, e.g., a source contact 134 to source region 108 and a drain contact 136 to drain region 110. Source contact 134 and drain contact 136 may define electrical couplings through first stack 104 as discussed in further detail herein. Each contact 124, 134, 136 may include the same material and/or similar materials to those discussed herein relative to first plate 122. Contacts 124, 134, 136 and other similar structures discussed herein (e.g., second contact(s) 152) also may include refractory metal liners (not separately shown) on their sidewalls to impede or prevent electromigration degradation, shorting to other components, etc.

Structure 100 includes second stack 144 over substrate 102, e.g., within a second ILD layer 140 (having a second insulative liner 142 thereon) and on first contact 124 to first stack 104. Second stack 144 may operate on similar principles to first stack 104 but may have a different switching voltage and furthermore may include components different from those in first stack 104. For example, second stack 144 may include a second conductive plate (“second plate”) 146 on first contact 124 and thus may lack gate dielectric layer 114. Second stack 144 may not include gate dielectric layer 114 as a result of not physically interfacing with channel region 106 or any other portion of substrate 102. Second plate 146 may include the same materials and/or similar materials to those in first plate 122 of first stack 104 and may be present for coupling first contact 124 to a second ferroelectric layer 148. Second ferroelectric layer 148 may have a different switching voltage from first ferroelectric layer 120, e.g., by being shaped differently and/or by having a different material composition from first ferroelectric layer 120.

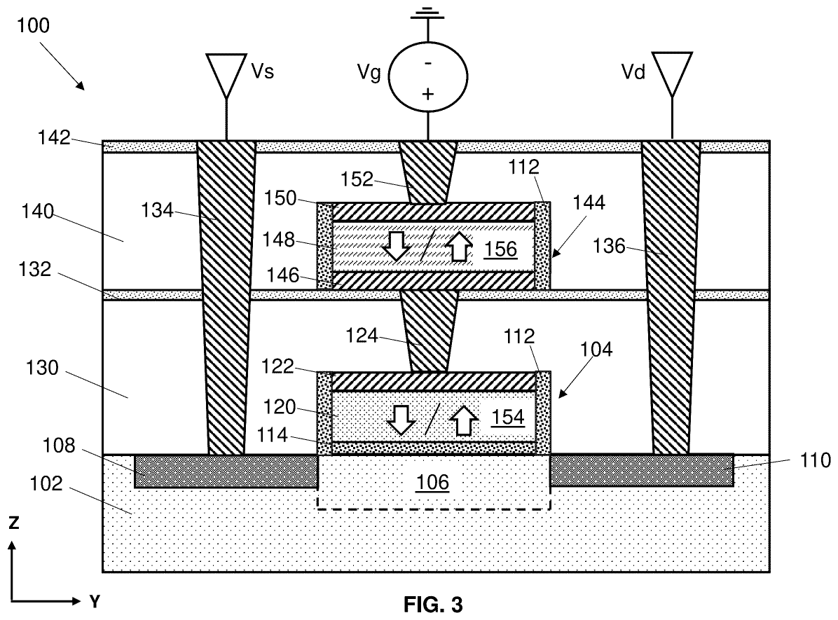

In embodiments of structure 100, second stack 144 may include second ferroelectric layer 148 with a larger or smaller switching voltage than that of first ferroelectric layer 120; structure 100 may be operable to store multiple bits in either case, as discussed herein. Preferably, the difference in switching voltage between ferroelectric layers 120, 148 can be sufficiently large to prevent inadvertent switching of both ferroelectric layers 120, 148 when an operator desires to program only one of the layers 120, 148. For instance, where first ferroelectric layer 120 has a switching voltage with a magnitude of approximately 4.0 V (whether positive or negative), as discussed herein, second ferroelectric layer 148 may have a switching voltage with a magnitude of approximately 2.0 V. In further embodiments, these voltage magnitudes may be the opposite for each ferroelectric layer 120, 148, and/or different values may be used. Various approaches for distinguishing the switching voltages in each ferroelectric layer 120, 148 for each stack 104, 144 are discussed herein and certain examples are illustrated in FIGS. 3-6. During operation, second stack 144 does not operate as a transistor (i.e., by not controlling conductivity in a channel region thereunder) but instead functions a capacitor, e.g., by selectively storing a logic level in first ferroelectric layer 120 via the switchable field orientation therein.

Second stack 144 may include a third conductive plate (“third plate”) 150 on second ferroelectric layer 148, e.g., for coupling to one or more contacts thereon in a manner similar to first plate 122 of first stack 104. A second contact 152 may couple second stack 144 to overlying metal wires and/or vias for coupling to a gate voltage Vg applied to structure 100.

In other words, second stack 144 can be a ferroelectric capacitor (e.g., a metal-ferroelectric-metal (MFM) capacitor) with a bottom conductive plate (i.e., second conductive plate 146) electrically connected by contact 124 to the first stack 104 (i.e., to the gate of the FeFET below) and with a top conductive plate (i.e., third conductive plate 150) electrically connected by contact 152 to receive Vg.

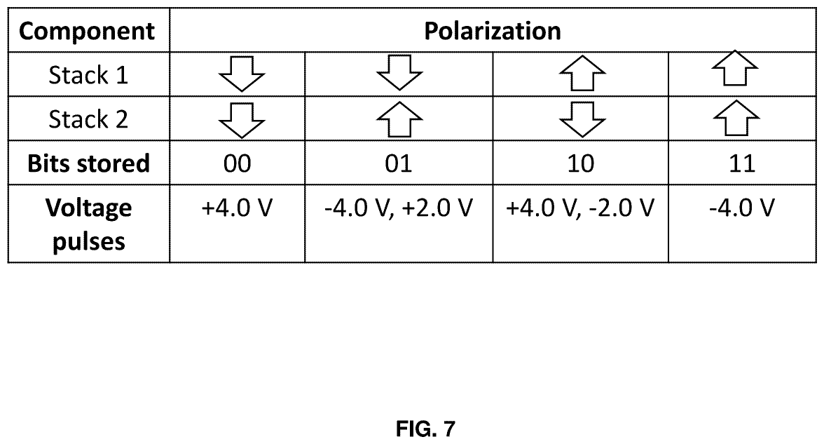

In the arrangement shown, contacts 124, 152 form a series coupling from gate voltage Vg to substrate 102 through each stack 104, 144. Gate voltage Vg thus can be applied to each stack 104, 144 and may be controlled to program none, only one, or all stacks 104, 144 in the series coupling based on the magnitude of voltages applied thereto. An operator may pulse multiple gate voltage magnitudes through stacks 104, 144, to switch their electric field orientations as needed to store a desired set of bits, as discussed elsewhere herein relative to FIG. 7.

A drain voltage (Vd) may be coupled to drain contact 136 and a source voltage (Vs) may be coupled to source contact 134. During a pre-charge operation, drain voltage Vd is tied to a supply voltage and source voltage Vs is tied to ground, but these may be switched and/or replaced with different voltage levels in further implementations. The electric field orientation in first stack 104 may control whether channel region 106 electrically couples source region 108 to drain 110, and thus may indicate a “one” or a “zero” based on whether drain voltage Vd is coupled to source voltage Vs (e.g., whether Vd is set to ground in the example of FIG. 2). By contrast, the memory state of second stack 144 may be indicated based on the detectable capacitance within second stack 144, e.g., by applying a read voltage via gate voltage Vg, when such a voltage has a magnitude less than the switching voltages of each stack 104, 144. Thus, embodiments of structure 100 provide a “one transistor one capacitor” (“1T1C”) memory architecture via ferroelectric layers 120, 148 but using only the surface area for one transistor on substrate 102. Embodiments of the disclosure include a variety of physical mechanisms for providing different switching voltages in each stack 104, 144 via ferroelectric layers 120, 148 with different switching voltages. Each of the various implementations described herein may be used together where desired and applicable, e.g., to further adjust the difference in switching voltages between each stack 104, 144.

FIG. 3 depicts an example implementation of structure 100 in which first ferroelectric layer 120 includes a first material composition 154 having the first switching voltage and second ferroelectric layer 148 includes a second material composition 156 (indicated with different cross-hatching) having the second switching voltage. Stacks 104, 144 and ferroelectric layers 120, 148 therein, in all other respects, may be substantially identical and/or otherwise structurally indistinguishable apart from material compositions 154, 156 of each ferroelectric layer 120, 148. According to embodiments, any two material compositions 154, 156 may be used in each stack 104, 144 so long as the material(s) have ferroelectric properties and switching voltages that are sufficiently different for each stack 104, 144 to have an electric field that may be switched independently of the other stack 104, 144. For instance, material compositions 154, 156 may have switching voltages that are at least approximately 0.5 V different from each other, but it is understood that larger or smaller voltage differences are possible in various implementations. According to a more specific example, first ferroelectric layer 120 may include hafnium oxide (HfO₂) and second ferroelectric layer 148 may include hafnium-zirconium oxide (HZO). In this example, first ferroelectric layer 120 may have a switching voltage of approximately 2.0 V and second ferroelectric layer 148 may have a switching voltage of approximately 4.0 V. The different material compositions 154, 156, without further structural differences between stacks 104, 144, may allow different levels of gate voltage Vg to program only one of the two stacks 104, 144 to be programmed (i.e., reverse the orientation of the electric field) at varying voltage strengths. To provide structure 100 in this example, the forming of each stack 104, 144 may include forming (e.g., by deposition) different ferroelectric materials for each stack, but otherwise forming stacks 104, 144 through similar techniques.

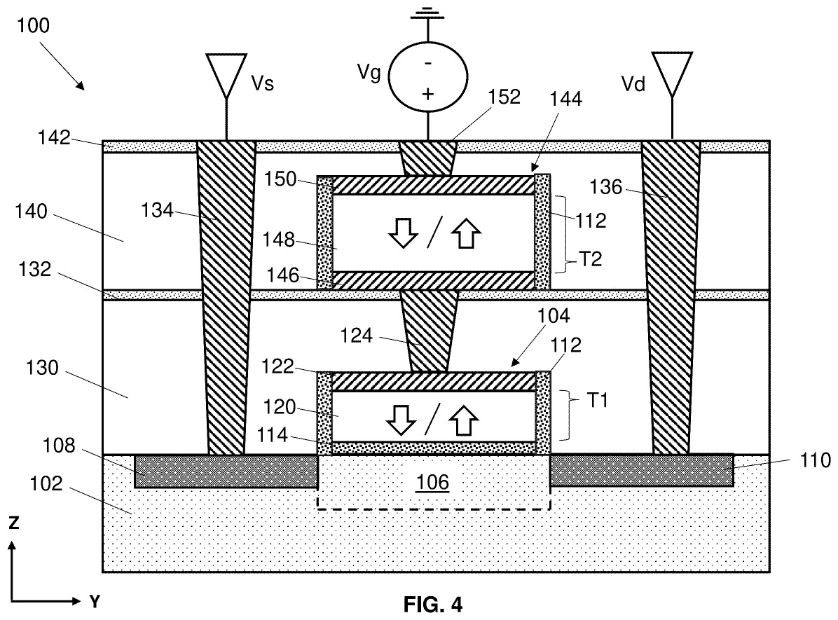

Turning to FIG. 4, further implementations of structure 100 may include stacks 104, 144 in which ferroelectric layers 120, 148 may have the same or similar compositions, but in which each ferroelectric layer 120, 148 has a different vertical thickness. It is again emphasized that each ferroelectric layer 120, 148 optionally may have a distinct material composition (e.g., as shown in FIG. 3 and discussed herein), but this is not necessarily required. First ferroelectric layer 120 may have a first thickness T1 that is different from a second thickness T2 of second ferroelectric layer 148, i.e., each ferroelectric layer 120, 148 may provide significantly different amounts of electric insulation and/or charge storage if the switching voltage of each ferroelectric layer 120, 148 varies from intrinsic crystalline phase changes. Such crystalline phase changes from thickness, when present, may cause one stack 104, 144 to exhibit a larger voltage drop and thus a smaller switching voltage (i.e., lower biasing voltages are sufficient to produce a voltage drop for switching the orientation of ferroelectric layer(s) 120, 148). According to an example, first ferroelectric layer 120 may have first thickness T1 of approximately ten nanometers (nm), and second ferroelectric layer 148 may have second thickness T2 of approximately twenty nm, such that the switching voltage magnitude of first ferroelectric layer 120 is less than the switching voltage magnitude of second ferroelectric layer 148.

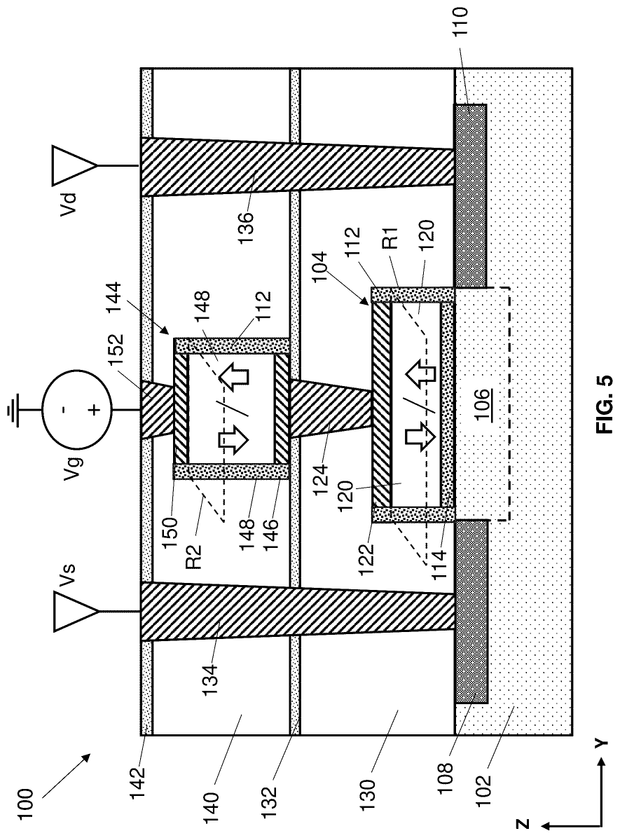

Turning to FIG. 5, the difference in switching voltages for each stack 104, 144 may be implemented through still other physical differences between ferroelectric layers, 120, 148. The differences in size between each ferroelectric layer 120, 148 need not be limited to vertical thickness (i.e., height along Z axis), but additionally or alternatively arise from differences in cross-sectional area (e.g., area within X-Y plane). First ferroelectric layer 120 thus may have a first cross-sectional area R1 (indicated as extending out of the page by dashed lines) that is larger than a second cross-sectional area R2 for second ferroelectric layer 148. In still further embodiments, cross-sectional area R2 may be larger than cross-sectional area R1. Larger cross-sectional areas may be associated with larger voltage drops (i.e., they have the opposite relationship on voltage drop from larger thicknesses) across the material(s) within ferroelectric layer(s) 120, 148. According to an example, first cross-sectional area R1 for first ferroelectric layer 120 is larger and provides a larger voltage drop (and thus a higher magnitude switching voltage) than across second ferroelectric layer 148 having a smaller cross-sectional area. These differences in cross-sectional area, where desired, may be provided in addition to (or separately from) any differences in vertical thickness and/or material composition discussed herein.

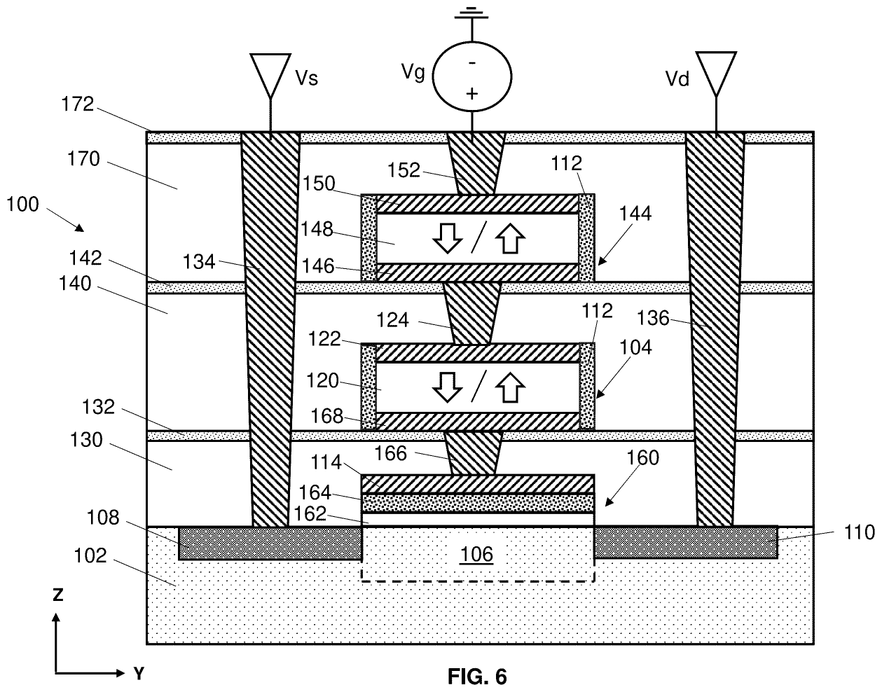

FIG. 6 depicts a further implementation of structure 100 in which each stack 104, 144 is provided within a back end layer of a device (i.e., within ILD layer 140, and a third ILD layer 170 with third insulative liner 172 thereon, that are not on substrate 102). In this case, structure 100 may take the form of a two capacitor memory cell instead of a “1T1C” configuration discussed elsewhere herein. As shown, structure 100 may include a metal insulator semiconductor (MIS) capacitor 160 or other diode structure on substrate 102. MIS capacitor 160, or other types of capacitors, may provide a capacitive junction between stacks 104, 144 and certain portions of substrate 102. MIS capacitor 160 may be operationally similar to field effect transistors (FETs) apart from the presence of a capacitive junction therein, and thus channel region 106 and S/D regions 108, 110 may remain present in substrate 102. In further embodiments, MIS capacitor 160 may be substituted for a conventional gate stack. MIS stack 160 may be free of any ferroelectric materials therein, and thus may not be capable of storing data through electric field orientation.

MIS stack 160 may include, e.g., an interfacial layer 162 on channel region 106. Interfacial layer 162 may be an insulative material (e.g., oxide and/or nitride based insulators) selected specifically to increase the voltage bias needed to operate interconnected stacks 104, 144, while maintaining a capacitive junction between channel region 106 and components in other wiring levels coupled to MIS stack 160. According to an example, interfacial layer 162 may include hafnium oxide (HfO₂) or other materials appropriate for use within ferroelectric layers 120, 148, but to a much smaller thickness (e.g., five nm or less) such that any electric fields formed therein cannot be switched between orientations. MIS stack 160 additionally may include gate dielectric layer 114 on interfacial layer 162 to prevent electrical shorting to substrate 102 and to maintain the desired capacitive junction. Interfacial layer 162 and gate dielectric layer 114 together may define the “insulator” portion of MIS stack 160. MIS stack 160 also may include an upper plate 164 for providing the conductive (i.e., “metal”) portion of MIS stack 160. Upper plate 164 may include any of the various conductive materials discussed herein relative to other components. A front end contact 166 may couple MIS stack 160 (or other structures, e.g., a transistor gate) to first stack 104 located above substrate 102 and one or more of ILD layers 130, 140.

First stack 104 may be located over MIS stack 160 and/or other structures for coupling of stacks 104, 144 to substrate 102. First stack 104, however, may not include gate dielectric layer 114 but instead may include a lower plate 168 because first stack 104 does not physically interface with channel region 106 (or other areas of substrate 102). Here, first ferroelectric material 120 is between lower plate 168 and first plate 122, thus causing first ferroelectric material 120 to function as a capacitor structure and not as a hybrid capacitor-transistor structure. First stack 104 thus may be defined in a metal wiring layer instead of a device layer of structure 100. In this case, each stack 104, 144 may be in a different respective metal wiring layer over substrate 102. In all other respects, however, first stack 104 and second stack 144 may retain the various structural features and/or differences described herein relative to other embodiments. That is, first stack 104 and second stack 144 each may have a different switching voltage arising from one or more differences between them (i.e., different material compositions in each ferroelectric layer 120, 148, different vertical thicknesses, different cross-sectional areas, etc.).

Referring to FIG. 2, embodiments of the disclosure also provide methods of forming structure 100. Such methods may be implemented by combining various manufacturing techniques to yield stacks 104, 144 over substrate 102. In an example, methods of the disclosure may include forming first stack 104 over substrate 102 such that it has a desired first switching voltage. The desired switching voltage may be produced by selecting a particular material for use within ferroelectric layer 120, forming ferroelectric layer 120 with a desired thickness or surface area, etc., as discussed herein. In some cases, the forming of first stack 104 may occur in a wiring layer of a device, and not on a device layer where other transistors and/or active devices are provided on substrate 102. In further processing (e.g., back end of line (BEOL) stages), further processing may include forming second stack 144 serially coupled to first stack 104 in which second ferroelectric layer 148 has a different switching voltage from first ferroelectric layer 120. The desired switching voltage for second ferroelectric layer 148 may be produced by selecting a different material for use within ferroelectric layer 148 from that of ferroelectric layer 120, forming second ferroelectric layer 148 with a desired thickness or surface area, etc., from first ferroelectric layer 120, and/or by other modifications as discussed herein. Operation of structure 100 may include applying a voltage (e.g., gate voltage Vg) across stacks 104, 144 to adjust a bit stored in either or both stacks 104, 144. Since each stack has a different switching voltage, the applying of voltages to each stack 104, 144 may be implemented by multiple voltage pulses having different magnitudes.

Referring now to FIG. 2 and FIG. 7 together, embodiments of structure 100 are operable to store multiple bits of data using the electric field orientation of ferroelectric layers 120, 148 in each stack 104, 144. Structure 100 may differ from conventional FeFET memory structures by having an operationally distinct read operation. Specifically, structure 100 does not operate using binary bitline sensing of data stored in each stack 104, 144. During a write operation, source terminal Vs and drain voltage Vd may be tied to ground and four different states can be achieved in stacks, 104, 144 by applying a high positive Vg, a high negative Vg, a high negative Vg followed by a mid-level positive Vg, or a high positive Vg followed by a mid-level negative Vg, as discussed herein.

FIG. 7 provides a table indicating four possible electric field orientations for two stacks, i.e., a down-down combination, a down-up combination, an up-down combination, and an up-up combination. These combinations may correspond to a corresponding two bit word, i.e., 00, 01, 10, or 11. It is understood that the correlation between field orientation and bit value may vary in different embodiments. In the example of FIG. 7, “stack 1” has a lower magnitude switching voltage (i.e., 2.0 V) and “stack 2” has a higher magnitude switching voltage (i.e., 4.0 V), but these are provided solely as examples. To store these values in stacks 104, 144 of structure 100, an operator may apply one or more voltage pulses to affect the electric field orientation of either or both stacks.

To provide a down-down orientation, an operator may apply a single +4.0 V pulse, which exceeds the switching voltage for each stack 104, 144 in the positive voltage domain. This may cause each stack 104, 144 to switch to an identical (e.g., downward) orientation. To provide a down-up orientation, the operator may apply a first −4.0V pulse, which exceeds the switching voltage for each stack 104, 144 in the negative voltage domain and causes each stack to switch to an identical (e.g., upward) orientation. Next, the operator applies an opposite polarity voltage of lower magnitude (e.g., +2.0 V as shown in FIG. 7). This opposite polarity pulse of lower magnitude is sufficient to invert the polarity of stack 1, but not sufficient to invert the polarity of stack 2. Hence, stack 1 will switch to a downward orientation whereas stack 2 remains in an upward orientation. These voltage pulses may have an opposite polarity (e.g., a +4.0 V pulse followed by a −2.0 V pulse) to provide the opposite orientations in each stack, e.g., producing an up-down orientation. To provide an up-up orientation, an operator may apply a single −4.0 V pulse to exceed the switching of each transistor in the negative voltage domain, thus producing identical orientations opposite those for the +4.0 V pulse.

Although embodiments of structure 100 are illustrated and described herein as having two stacks 104, 144, it is understood that more than two stacks may be provided in further implementations. For example, multiple second stacks 144 may be provided in multiple wiring layers of a structure such that an operator may store three or more bits in a row of serially coupled stacks. In this case, each interconnected stack may have a different switching voltage, and a series of three or more pulses may be operable to store any desired combination of bits in the three or more stacks. It is understood that such an array of stacks may be provided, e.g., by increasing the number of second stacks 144 in structure 100 through modifications which do not significantly differ from the structural and operational techniques discussed herein for structure 100 featuring only first stack 104 and one second stack 144.

Embodiments of the disclosure provide various technical and commercial advantages, examples of which are discussed herein. The disclosure provides a structure and related method to provide multiple bits of data in a relatively small surface area, i.e., by providing multiple ferroelectric memory stacks (e.g., first stack 104, second stack 144) in different layers. As compared to conventional memory devices, the serially coupled stacks may have different bits written thereto by using the different switching voltages in each stack and voltage pulses of decreasing magnitude. As discussed herein, two or more pulses of decreasing voltage magnitude are operable to change the field orientation in all stacks simultaneously, and then alter the field orientation of only one stack in a subsequent, lower magnitude voltage pulse. Embodiments of the disclosure thus may use multiple ferroelectric layers in combination with a device layer and one or more wiring layers to provide a hybrid data structure, e.g., based on multiple interconnected capacitive structures and/or by using a “1T1C” model for storing a set of bits.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing structures as part of either (a) an intermediate product, such as a motherboard, or (b) an end product. The end product can be any product that includes integrated circuit chips, ranging from toys and other low-end applications to advanced computer products having a display, a keyboard or other input structure, and a central processor.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
a first ferroelectric memory stack over a substrate, the first ferroelectric memory stack having a first switching voltage; and
a second ferroelectric memory stack serially coupled to the first ferroelectric memory stack over the substrate, the second ferroelectric memory stack having a second switching voltage different from the first switching voltage.

2. The structure of claim 1, wherein the first ferroelectric memory stack includes a first ferroelectric layer, and the second ferroelectric memory stack includes a second ferroelectric layer having a different material composition from the first ferroelectric layer.

3. The structure of claim 2, wherein the first ferroelectric layer includes hafnium oxide (HfO₂) and the second ferroelectric layer includes hafnium-zirconium oxide (HZO).

4. The structure of claim 1, wherein the first ferroelectric memory stack includes a first ferroelectric layer, and the second ferroelectric memory stack includes a second ferroelectric layer having a different cross-sectional area from the first ferroelectric layer.

5. The structure of claim 1, wherein the first ferroelectric memory stack is on a device layer, and wherein the second ferroelectric memory stack is within a metal wiring layer over the device layer.

6. The structure of claim 1, wherein the first ferroelectric memory stack and the second ferroelectric memory stack are each within a respective metal wiring layer above the substrate.

7. The structure of claim 6, further comprising a metal-insulator-semiconductor (MIS) capacitor on the substrate coupled to the first ferroelectric memory stack and the second memory stack.

8. The structure of claim 1, wherein a magnitude of the first switching voltage is approximately two volts (V) and a magnitude of the second switching voltage is approximately four V.

9. A structure comprising:
a first ferroelectric memory stack including:
an insulative layer on an upper surface of a substrate,
a first ferroelectric layer on the insulative layer, and
a first conductive plate on the first ferroelectric layer, wherein the first ferroelectric memory stack has a first switching voltage; and
a second ferroelectric memory stack within a metal wiring layer and serially coupled to the first ferroelectric memory stack, the second ferroelectric memory stack including:
a second conductive plate within the metal wiring layer,
a second ferroelectric layer on the second conductive plate, and
a third conductive plate on the second ferroelectric layer, wherein the second ferroelectric memory stack has a second switching voltage different from the first switching voltage such that a first bit stored within the second ferroelectric memory stack is independently adjustable relative to a second bit stored within the second ferroelectric memory stack.

10. The structure of claim 9, wherein the second ferroelectric layer has a different material composition from the first ferroelectric layer.

11. The structure of claim 10, wherein the first ferroelectric layer includes hafnium oxide (HfO₂) and the second ferroelectric layer includes hafnium-zirconium oxide (HZO).

12. The structure of claim 9, wherein the second ferroelectric layer has a different cross-sectional area from the first ferroelectric layer.

13. The structure of claim 9, wherein a magnitude of the first switching voltage is approximately two volts (V) and a magnitude of the second switching voltage is approximately four V.

14. A method comprising:
forming a first ferroelectric memory stack over a substrate, the first ferroelectric memory stack having a first switching voltage;
forming a second ferroelectric memory stack serially coupled to the first ferroelectric memory stack over the substrate, the second ferroelectric memory stack having a second switching voltage; and
applying a voltage across the first ferroelectric memory stack and the second ferroelectric memory stack to adjust one of a first bit stored within the first ferroelectric memory stack and a second bit stored within the second ferroelectric memory stack.

15. The method of claim 14, wherein forming the first ferroelectric memory stack includes forming a first ferroelectric layer, and forming the second ferroelectric memory stack includes forming a second ferroelectric layer having a different material composition from the first ferroelectric layer.

16. The method of claim 15, wherein the first ferroelectric layer includes hafnium oxide (HfO₂) and the second ferroelectric layer includes hafnium-zirconium oxide (HZO).

17. The method of claim 14, wherein the first ferroelectric memory stack and the second ferroelectric memory stack are each formed within a respective metal wiring layer above the substrate.

18. The method of claim 14, further comprising forming a metal-insulator-semiconductor (MIS) capacitor on the substrate coupled to the first ferroelectric memory stack and the second memory stack.

19. The method of claim 14, wherein the first ferroelectric memory stack includes forming a first ferroelectric layer, and the second ferroelectric memory stack includes forming a second ferroelectric layer having a different cross-sectional area from the first ferroelectric layer.

20. The method of claim 14, wherein the first ferroelectric memory stack is formed on a device layer, and wherein the second ferroelectric memory stack is formed within a metal wiring layer over the device layer.
